(19) United States
(12) Patent Application Publication
(10) Pub. No.: US 2026/0328823 A1
(43) Pub. Date: Oct. 22, 2026

(54) MEASUREMENT APPARATUS AND PROCESS FOR SENSING ELECTRO-MAGNETIC FIELDS USING RABI MATCHING ON A TWO-LEVEL QUANTUM SYSTEM

(71) Applicant: Government of the United States of America, as represented by the Secretary of Commerce, Gaithersburg, MD (US)

(72) Inventors: Andrew Peter Rotunno, Broomfield, CO (US); Christopher Lee Holloway, Boulder, CO (US); Matthew Thomas Simons, Lafayette, CO (US); Alexandra Brae Artusio-Glimpse, Boulder, CO (US); Nikunjkumar Rasikbhai Prajapati, Lafayette, CO (US); Samuel Berweger, Boulder, CO (US)

(21) Appl. No.: 19/110,345

(22) PCT Filed: Sep. 8, 2023
(86) PCT No.: PCT/US2023/032310

§ 371 Date: Mar. 10, 2025

Related U.S. Application Data
(60) Provisional application No. 63/404,628, filed on Sep. 8, 2022.

(51) Int. Cl. G01R 29/08

(52) U.S. Cl. CPC G01R 29/0885

(57) ABSTRACT

A process for measuring electromagnetic fields includes applying a near-resonant field to a quantum medium to create a two-level quantum system, tuning an effective Rabi frequency based on a predetermined frequency of interest, and probing the two-level system to thereby measure properties of an electromagnetic field near the predetermined frequency of interest.

### CROSS REFERENCE TO RELATED APPLICATIONS

This application claims priority to U.S. Provisional Patent Application Ser. No. 63/404,628 filed Sep. 8, 2022, the disclosure of which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### FIELD OF THE INVENTION

The present invention relates generally to sensing electromagnetic fields, and more particularly to sensing fields using a two-level quantum media.

### BACKGROUND

Detection of radio waves classically requires a wavelength-scale antenna to resonantly receive electromagnetic fields, both for field metrology and signal reception.

### SUMMARY OF INVENTION

Using atomic states such as highly-excited Rydberg energy levels allow detection of wavelengths that are much larger than the sensor size, preferably a few-cm³ sized atomic vapor cell. Many Rydberg resonances exist for calibrated measurement of electric field via Autler-Townes line splitting, but states with resonances below ~1 GHz are very highly excited, and difficult to interrogate. Proposed in more detail below is a method and apparatus to generate a quantum system which has resonant features at arbitrary frequency to cover the range from about 1 MHz to about 1 GHz. Exemplary embodiments expand techniques of Rydberg line splitting electrometry and resonant reception to a tunable frequency range. This allows for “self-calibrated” atomic field measurements via line splitting in a new frequency regime, as well as inherent Amplitude Modulation (AM) down-conversion for carriers in this range, and a version of a spectrum analyzer in a frequency-scanning mode. Exemplary embodiments enable a new type of resonant reception for radio waves in a small package and can be used for compact long-distance or over-the-horizon reception, where long wavelengths are preferred.

An exemplary embodiment includes a measurement apparatus which probes the energy of a quantum two-level system that is driven simultaneously by two different oscillating fields. The first field is resonant to the two-level system and controlled in power and detuning. The second field is much lower in frequency, either the external “target” field to be measured or applied directly in the apparatus to measure auxiliary fields.

In an exemplary embodiment, a pair of atomic Rydberg states are created and measured by two-color Electromagnetically Induced Transparency (EIT). Rydberg states have strong electric polarizability and transition dipole moments, making them more sensitive to electric field measurement than typical ground state atoms. By interrogating the state energies and populations using, for example, scanning laser spectroscopy, and appropriate quantum theory, one can determine the strength of the fields applied. Additionally, the fact of a line splitting means that by locking lasers and resonant field power, one can receive signals at arbitrary frequency to include the High Frequency and Very High Frequency radio bands (for example, and without limitation, from about 1 MHz to about 1 GHz) and beyond with various optimizations. The use of a line-splitting for typically off-resonant signals enables reception for radio waves that are many orders larger in size than the physical sensor head, e.g., a few-cm³ atomic vapor cell. The further elimination of the need for radio down-mixing electronics and high sampling rate for carrier frequencies are severely relaxed by exemplary embodiments, making them significant improvements in terms of the space, weight, and power (SWaP) over a radio receiver.

According to one aspect of the invention, a measurement apparatus for sensing electro-magnetic fields includes a quantum medium; a resonant field source configured to excite the quantum medium to a two-level quantum system; a controller configured to tune an effective Rabi frequency of the two-level quantum system based on a predetermined frequency of interest; and an interrogator configured to probe the two-level system, thereby measuring properties of an external electromagnetic field near the predetermined frequency of interest.

Optionally, the interrogator includes a laser source and a photo diode configured to receive an interrogation beam emitted by the laser source through the two-level quantum system.

Optionally, the measurement apparatus includes an off-resonant field source configured to cause a Townes-Merritt effect in the two-level system by applying an off-resonant field to the two-level system.

According to another aspect of the invention a process for measuring electromagnetic fields includes applying a near-resonant field to a quantum medium to create a two-level quantum system; tuning an effective Rabi frequency based on a predetermined frequency of interest; and probing the two-level system to thereby measure properties of an electromagnetic field near the predetermined frequency of interest.

Optionally, the step of probing includes using a two-photon ladder scheme electromagnetically induced transparency wherein a frequency of a first laser is swept while a transmission through the two-level quantum system of a second laser is monitored.

Optionally, the process includes applying an off-resonant field to the two-level quantum system, the off-resonant field having an amplitude of sufficient magnitude to cause a Townes-Merritt splitting effect.

Optionally, the process includes iteratively comparing observed spectra obtained during the step of probing and calculations of a quantum state of the two-level quantum system.

Optionally, the process includes scanning the effective Rabi frequency across a target frequency value; and measuring an energy spectrum at each scanned frequency.

Optionally, the process incudes using the measured energy spectra to determine afield amplitude that caused any observed splitting across the target frequency value.

Optionally, the predetermined frequency of interest is an amplitude-modulated carrier frequency, and the step of probing includes probing continuously at a fixed sensitive location.

Optionally, the fixed sensitive location is one of a center of an unsplit peak, or a high-slope edge of spectral lines.

Optionally, the predetermined frequency of interest is a frequency-modulated carrier frequency, and the step of probing includes probing continuously at a fixed sensitive location.

Optionally, the fixed sensitive location is at a center of either splitting peak, and wherein reactions to a signal will have opposite reactions to a sign of a difference in frequency between the Rabi frequency and the off-resonant frequency.

Optionally, the process includes applying an off-resonant field having a frequency within one effective linewidth of the energy probing system of a target frequency; adjusting an amplitude and frequency of the resonant field and an amplitude of the off-resonant field to partially split a spectral line, thereby making the location sensitive to perturbations in field amplitude that are small relative amplitudes of the applied fields; and wherein the step of probing includes continuously measuring amplitude of a beat-note frequency at a sensitive location, thereby measuring an amplitude of an external field at the target frequency.

Optionally, the sensitive location is one of a center of an unsplit peak, or a high-slope edge of spectral lines.

Optionally, the process includes applying an off-resonant field having a frequency within one linewidth of a target frequency; adjusting an amplitude and frequency of the resonant field and an amplitude of the off-resonant field to partially split a spectral line, thereby making the location sensitive to perturbations in field amplitude that are small relative amplitudes of the applied fields; and wherein the step of probing includes continuously measuring modulations of rate of a beat-note frequency at a sensitive location, thereby measuring phase and amplitude of an external field at the target frequency.

Optionally, the sensitive location is one of a center of an unsplit peak, a high-slope edge of spectral lines, or a 1-o point of a Gaussian spectral curve.

According to another aspect of the invention, a process for measuring electromagnetic fields includes applying a near-resonant field to a quantum medium to create a two-level quantum system; iteratively scanning through values of Rabi frequency; probing the two-level system at each scanned Rabi frequency; and analyzing patterns from the probing to determine frequency and intensity of incident off-resonant fields.

Optionally, the process includes iteratively applying an off-resonant field configured as a local oscillator; and probing the two-level system at each value of the local oscillator.

Optionally, the step of analyzing includes looking for additional intermodulation tones.

The foregoing and other features of the invention are hereinafter described in greater detail with reference to the accompanying drawings.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows, according to some embodiments, a generalized schematic representation of a measurement apparatus.

FIG. 2 shows, according to some embodiments, a representation of the effect of a resonant field on the energy levels of a two-level quantum system in atoms, as well as the energy spectroscopy which can be used in measurement.

FIG. 3 shows, according to some embodiments, an example of an energy shift of one of the quantum states, which when modulated in time, demonstrate the Townes-Merritt effect which produces effective atom-photon energy states also called “Floquet sidebands” of the state.

FIG. 4 shows, according to some embodiments, spectral splitting when the resonant field's Rabi frequency is nearly equal to the off-resonant frequency ω_{Off}.

FIG. 5 shows, according to some embodiments, a schematic representation of a measurement apparatus.

FIG. 6 shows an exemplary embodiment of a Rydberg system, probed by laser EIT, using external plates and a microwave horn.

FIG. 7 shows energy spectroscopy from an exemplary embodiment.

FIG. 8 shows, according to some embodiments, a process for creating and interrogating a two-level quantum system.

FIG. 9 shows, according to some embodiments, a process for pseudo-resonant electrometry for AC fields.

FIG. 10 shows, according to some embodiments, a process for pseudo-resonant electrometry for DC fields.

FIG. 11 shows, according to some embodiments, a process for electrometry by measuring splittings across the resonance and fitting the curves.

FIG. 12 shows, according to some embodiments, a process for strong field AM reception by splitting, with automatic down-conversion using a tunable pseudo-resonance.

FIG. 13 shows, according to some embodiments, a process for strong field FM reception by splitting, with automatic down-conversion using a tunable pseudo-resonance.

FIG. 14 shows, according to some embodiments, a process for weak-field electrometry.

FIG. 15 shows, according to some embodiments, a process for a phase-amplitude receiver.

FIG. 16 shows, according to some embodiments, a process for a spectrum analyzer.

FIG. 17 shows, according to some embodiments, a process for a spectrum analyzer using frequency mixing.

### DETAILED DESCRIPTION

A detailed description of one or more embodiments is presented herein by way of exemplification and not limitation.

It is noted that, throughout the description, propagating and time-evolving electric fields acting on atomic excited Rydberg states measured by laser spectroscopy is discussed. Although not required, these phenomena represent a favorable quantum system to observe an exemplary effect. In an exemplary embodiment, a two-level quantum system is acted upon and a resulting energy structure is measured.

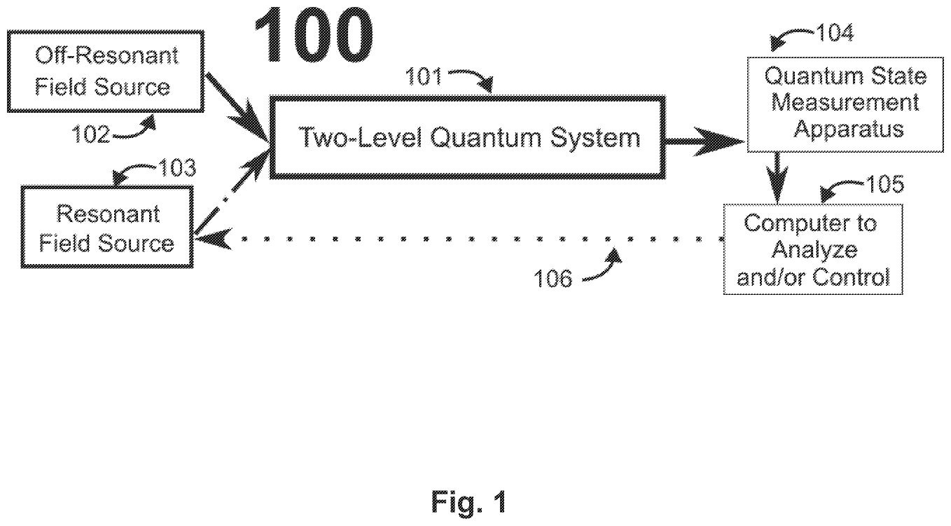

Referring first to FIG. 1, an exemplary measurement apparatus 100 is shown in schematic representation. Two quantum levels 101 are acted on simultaneously by two fields: one resonant and one off-resonant. The off-resonant field ω_{Off} modulates the state's energy at a rate many times smaller in frequency (ω_{Off}<<ω₀) than the two-level resonance ω₀, and is generated by an off-resonant field source 102. The resonant frequency is nearly equal to the atomic transition ω_{Res}√ω₀, and is generated by a tunable resonant field source 103. By measuring a resultant quantum state with an interrogator 104, an analyzer 105 can determine the resultant energy spectrum and compare with quantum theory to thereby measure parameters of the off-resonant field (such as, e.g., frequency and intensity), as well as perturbations in these parameters over time for reception of information, and those of additional fields. Apparatus controller 106 can be used to scan, lock, move, or otherwise control the resonant field in frequency and amplitude produced by the resonant field source 103, while being measured by interrogator 104.

In exemplary embodiments, the method of application of the resonant 103 and optional off-resonant 102 fields affect the measurement in terms of quality, dynamic range, polarization, and additional relevant features of any measurement using this invention. The resonant field 103 is at times desired to be a single value of amplitude over the extent of the two-level quantum system 101 sampled by the interrogator 104, requiring spatial uniformity of the resonant field 103 amplitude. In exemplary embodiments, either the resonant field 103 and/or the optional applied off-resonant field 102 can be applied directly using time-evolving near fields or from propagating radio waves. Physical embodiments of such structures include gain horns, dipole antennas, other resonant antenna structures, parallel plates, twin-lead waveguides, microstrip waveguides, or coplanar waveguides, for example. Propagating radio waves may optionally be enhanced by the used of meta-material structures embedded in the apparatus.

In exemplary embodiments the interrogator is used to obtain information about the off-resonant field source 102. It should be noted that off-resonant field source 102 may instead be tunable by controller 106, in order to measure additional fields (discussed later).

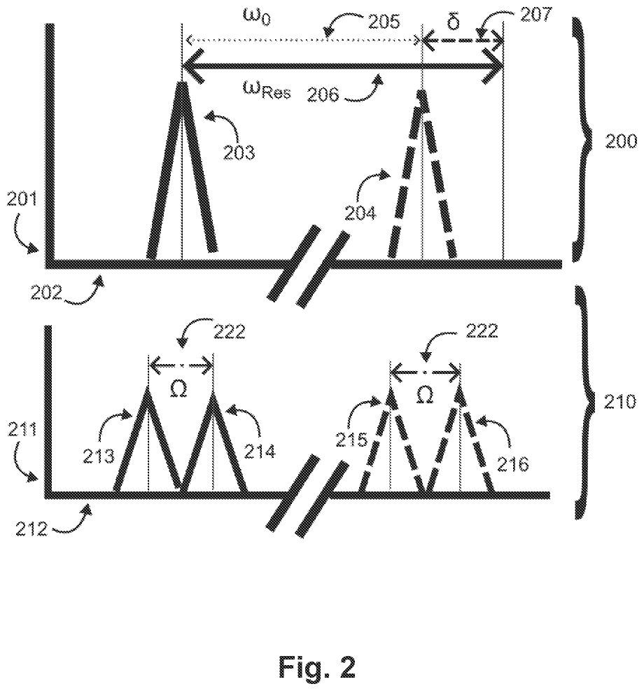

FIG. 2 represents the effect of a resonant field on the energy levels of the atoms, as well as the energy spectroscopy which can be used in measurement. Graph 200 shows an example of spectroscopy of atomic states, where on the vertical axis 201 represents optical transmitted power through an atomic vapor cell with arbitrary scaling and offset, plotted as a function on the horizontal axis 202 of laser frequency, with an offset and a significant gap between relevant spectral features. The spectral features are a sharp change in absorption near a certain frequency corresponding to a state's energy. The peak 203 represents a state which is allowed to be observed, and the peak 204 represents a state that is not necessarily detected or detectable due to not having an allowed transition to a probing state, although it has an allowed transition to the observable state 203. The energy gap between states is represented with the symbol ω₀, or the dotted arrow 205. This frequency includes any additional energy shifts due to additional fields. The applied resonant field 206 with frequency ω_{Res} represented by the solid arrow is near, but not necessarily equal to the atomic energy gap ω₀ 205. The difference is parametrized by the detuning 207 or δ represented by the dashed arrow. When the resonant field 206 is applied with significant amplitude and small detuning 207, we observe the Autler-Townes (AT) effect, illustrated in graph 210.

We illustrate again transmitted optical power on the vertical axis 211 against laser detuning on the horizontal axis 212. The Autler-Townes effect is a splitting of a spectral line when a significant amplitude of a resonant field is applied: the state observed at peak 203 is now observed at two locations 213 and 214, due to the interaction with the other state (as used here, “significant amplitude” means sufficient to cause a detectable effect when probed). Similarly, the state that can be observed at peak 204 is seen at two peaks 215 and 216 if probed. Notably, in the resonant case (207 δ=0), the two lines are separated by a quantity known as the Rabi Frequency 222 or Ω, represented by the dot-dashed arrows. The value of the Rabi Frequency is given by

$$Ω \frac{h}{2 π} = d \cdot {F}_{Res} \qquad ( 1 )$$

where h/2π is Planck's reduced constant, d is the dipole transition strength of the two-level interaction, and F_{Res} is the resonant electric field amplitude that drove the interaction. Notably, this converts the driving field amplitude into an energy difference measured in frequency by a line splitting. There is a simple extension to off-resonant (detuning 207 δ≠0) operation, where the lines will be split by an amount called the generalized Rabi Frequency:

Ω′=\sqrt{Ω²+δ²}. (2)

Additionally, the peak heights will unbalance by a known amount depending on detuning δ 207 and Rabi frequency Ω 222. Preferrably, this is operated as close to on resonance (ω₀=ω_{Res}) as possible, although other exemplary embodiments may operate with detunings up to a few multiples of the Rabi Frequency.

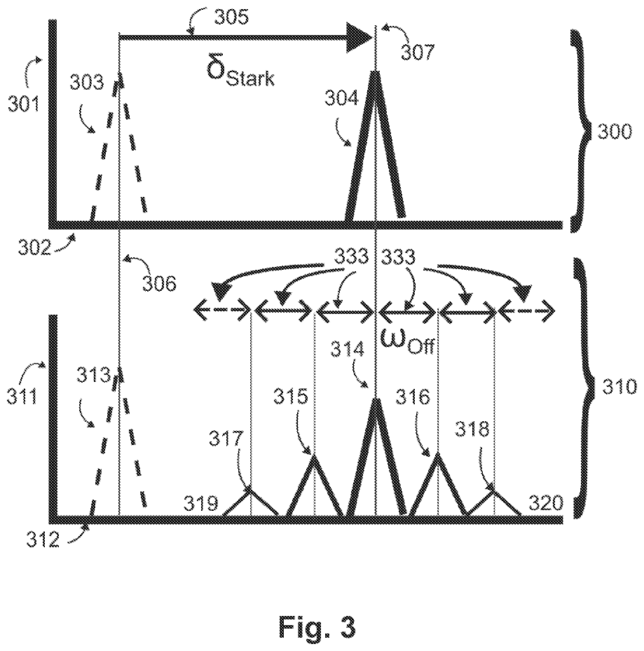

FIG. 3 illustrates an example of an energy shift of one of the quantum states, which when modulated in time, produces effective energy “sidebands” of the state. Consider the case of a quadratic shift in energy with field amount, such as the electric field Stark shift for atoms. Graph 300 shows spectral absorption lines on a vertical axis 301 of laser transmission against laser frequency on the horizontal axis 302. In the absence of a strong external electric field, one would observe the state near the spectral peak given by 303. However, due to the application of an electric field, the state is observed at a different energy, given by peak 304, which is shifted by the Stark shift δ_{Stark} 305.

In the low field limit, states are perturbed quadratically with field, as

$${δ}_{Stark} \cdot \frac{h}{2 π} = - \frac{α {F}_{D C}^{2}}{2} , \qquad ( 3 )$$

where α is the state's electric polarizability, F_{DC} is a steady state or direct current (DC) electric field.

For the case of an off-resonant field causing a Stark shift, many field values are experienced, but the state is shifted by the non-zero time average, given by the root-mean-squared amplitude F_{Off}/\sqrt{2}:

$${δ}_{Stark} \cdot \frac{h}{2 π} = - \frac{α {F}_{Off}^{2}}{4} . \qquad ( 4 )$$

It is this off-resonant alternating current (AC) Stark energy 307 that is shared between the plots 300 and 310. Graph 310 illustrates the observation of sidebands in transmission 311 over laser frequency 312, when a state's energy 313 is modulated by an off-resonant field 333, ω_{Off}.

In the case of an applied off-resonant AC field 333 with frequency ω_{Off}, the line shifts 305 from the zero-field location with energy 313 to energy 314, with Stark-shifted value by the above relations:

$${δ}_{Stark} \cdot \frac{h}{2 π} = - \frac{α}{2} ( {F}_{D C}^{2} + \frac{{F}_{Off}^{2}}{2} ) . \qquad ( 5 )$$

In addition to the peak shift from 313 to 314/307 by the Stark shift 305, we observe additional changes: first an amplitude shift in the central line 314, as well as the appearance of additional lines at integer multiples of the off-resonant frequency 333 (N*ω_{Off}) on both sides of the central peak 314.

Taking the simpler case of no DC field present, and if the energy shift has a quadratic dependence on the field, then the effective energy modulation frequency is rectified to a rate of 2ω_{Off}, and the Floquet sidebands appear at integer multiples as N*2ω_{Off} away from the center peak. The relative height of these peaks are given by Bessel functions with an argument of the modulation depth divided by the modulation rate:

$${J}_{N}^{2} ( \frac{α {F}_{Off}^{2}}{8 \frac{h}{2 π} {ω}_{Off}} ) , \qquad ( 6 )$$

where the N=0 peak is the center peak 314, the ‘first order’ peaks have N=±1 and appear 2ω_{Off} away from peak 314, the ‘second order’ peaks have N=±2 and appear 4ω_{Off} away from peak 314, and so on. In the general case, the DC field breaks the symmetry and odd-ordered peaks appear in the system, effectively combining effects from modulations at ω_{Off} and 2ω_{Off}. The population in sidebands, or the height of the observed spectral peaks of N^{th} order (located at δ_{Stark}+Nω_{Off} for N from −infinity to infinity, mostly the 0, ±1, ±2, . . . ) in the general case can be written in the form of a sum over possible combinations of multiple Bessel functions of different frequencies which combine to form Nth order side band:

$${\sum }_{m = - ∞}^{∞} {J}_{N - 2 m} ( \frac{α {F}_{D C} {F}_{Off}}{\frac{h}{2 π} {ω}_{Off}} ) {J}_{m} ( \frac{α {F}_{Off}^{2}}{8 \frac{h}{2 π} {ω}_{Off}} ) . \qquad ( 7 )$$

This lets us predict the peak heights of the sidebands, and we can now identify the Floquet sidebands illustrated in graph 310. The center line 314 represents the time-averaged energy of the state being modulated in energy by the off-resonant field 333 ω_{Off}. Relative to the shifted line 314, there are energy states with −1ω_{Off} h/2π peak 315 and at +1ω_{Off} h/2π peak 316. These lines primarily represent a ‘cross term’ where both fields F_{DC} and F_{Off} significantly affect the population at that energy.

Relative to the shifted line 314, there are energy states with −2ω_{Off} h/2π peak 317 and at +2ω_{Off} h/2π peak 318. These lines primarily represent an ‘ac intensity term’ where F_{Off}² scales population at that energy.

Deriving a direct calculation of electric field includes inverting a combination of Bessel functions. Exemplary embodiments can use methods such as taking ratios of peak heights, with closed-form expressions for relations between Bessel functions which may be an improvement over calculating each peak for providing convenient measurements of field.

Additional lines represented by 319 and 320 can exist for significant driving amplitude and may be ignored in exemplary embodiments. This sideband generation method is a known method for measuring electric fields of arbitrary frequency but uses line peak height ratios in the transmission axis as the measurement.

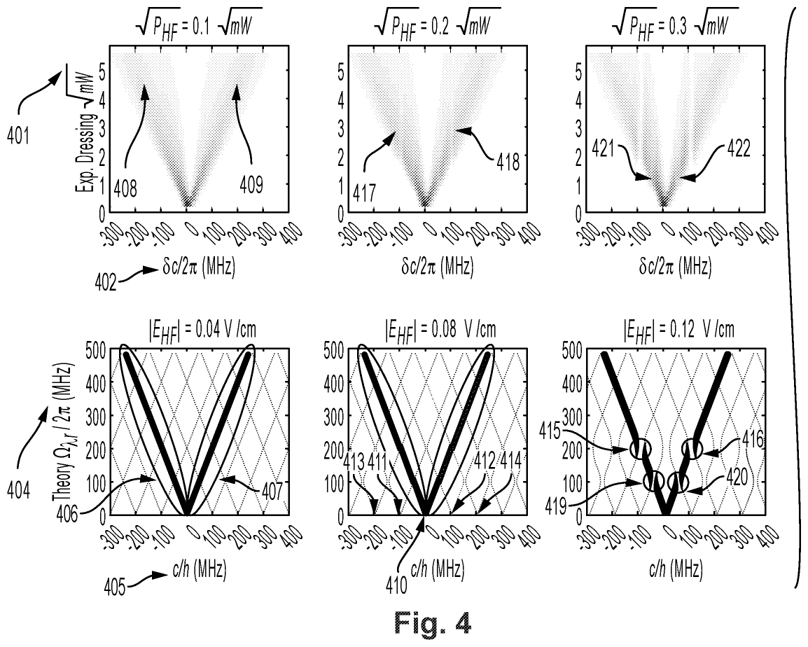

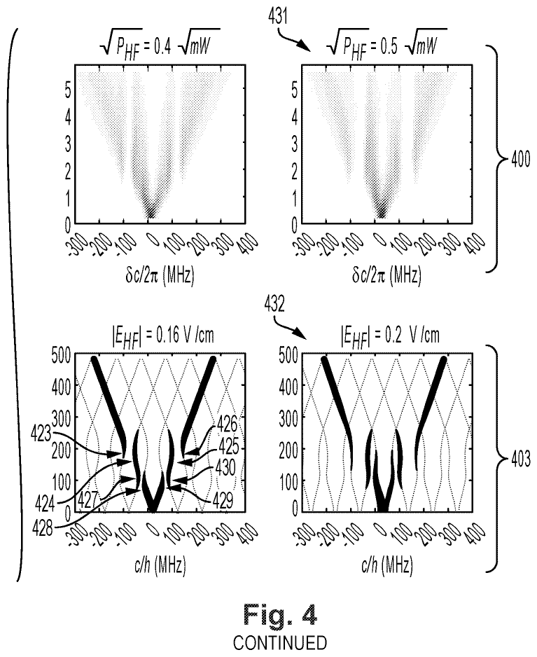

FIG. 4 presents both data 400 and calculated theory 403 for the central effect, which is used in exemplary embodiments, namely additional spectral splittings observed when the resonant field's Rabi frequency is nearly equal to the off-resonant frequency ω_{Off} and 2ω_{Off}. The experimental data in the row of graphs 400 plots laser spectroscopy frequency scan on the horizontal axis 402, using the white-black axis to represent differential optical transmittance through an alkali (Cesium) vapor cell. One level of a two-level system is measured, which is subject to the resonant field. The amplitude of the resonant field is controllably scanned, which is given as the ‘waterfall’ vertical axis 401, increasing from bottom to top. The Autler-Townes effect becomes ‘smeared’ from a dean line into a significantly broadened line in the experimental data 400 is due to non-uniform resonant field amplitude. Over the sample volume that the two-level quantum system is measured, a range of Rabi frequencies Ω are observed simultaneously, and this has the effect of broadening the line. However, the stability of the additional line splitting in the spectrum serves to illustrate that although many Rabi Frequency values are present in the system, only those which then interact with the sidebands when Ω≈ω_{Off} and Ω≈2ω_{Off} are significant in the effect at this second splitting. The off-resonant field amplitude is also varied and given by the plot titles 431, 432 for experiment and theory, respectively, increased from left to right. Calculations of the quantum theory of an exemplary embodiment may be found, for example, and are referenced herein: Rotunno, Andrew P., et al. “Detection of HF and VHF Fields through Floquet Sideband Gaps by ‘Rabi Matching’ Dressed Rydberg Atoms.” arXiv:2212.03304 (2022) accessible at https://arxiv.org/abs/2212.03304, which is hereby incorporated herein in its entirety. A significant Stark shift δ_{Stark} requires adjustment of the resonant field frequency ω_{Res}≈ω₀+δ_{Stark}. Exemplary embodiments may utilize this optional technique to keep additional effects from appearing, like population imbalance from detuning, typical dressed atoms stuff near resonance, typically normalized by ratio δ/Ω, e.g. Theoretical predictions are shown in the row of graphs 403, which result from numerical diagonalization of the Hamiltonian of the system. State energy is plotted in “quasi-energy” space on the horizontal axis 405, as well as state population as the size of the marker. The quantum states are calculated over a range of resonant field amplitudes, which is given as the ‘waterfall’ vertical axis 404, increasing from bottom to top. The effect of an Autler-Townes line splitting due to the resonant field increasing amplitude is given by the data by the dark regions in experiment and thick markers in the theory representing the |−> state marked by 406 and 408, and the |+> state marked by 407 and 409, in typical two-level dressed atom analysis. These features are repeated across graphs, and as the amplitude increases, deviations from this structure represent a new line-splitting measurement of the off-resonant field. The Townes-Merritt or Floquet sidebands are marked in the theory graph as the central line 410, first order lines 411 and 412, second order lines 413 and 414, and additional lines which do not significantly split in the following effect. Note that each of these energy states undergoes a similar Autler-Townes splitting with two diagonal lines (analogous to |−> 406 and |+> 407) extending from each Floquet sideband 411, 412, 413, 414. Exemplary embodiments focus in on the “cross-over” or avoided level crossing, or line splitting effect, where two pairs of line splittings occur in the spectrum and grow as a non-linear function of F_{Off}. The peak height and locations can be measured and analyzed to perceive and understand the fields that produced this system.

The crossover between the 0 order splitting Autler-Townes states and the opposite-AT state of the first order floquet sideband is observed to occur when Ω≈ω_{Off}. This line splitting is marked in the theory plots at 419 and 420, and the experiment plots as the absorption dips marked 421 and 422. When the field's ‘cross term’ F_{Off}*F_{DC} is strong enough that we can measure a line splitting (splitting larger than the resolved linewidth), on the theory plots the splitting 419 causes lines 427 and 428 to appear and splitting 420 causes lines 429 and 430 to appear. This effect is observed in the experimental graphs 400 at the energies corresponding to 421 and 422 on each graph.

The crossover between the 0 order splitting Autler-Townes states and the opposite-AT state of the second order Floquet sideband, observed to occur when Ω≈2ω_{Off}. This line splitting is marked in the theory plots at 415 and 416, and the experiment plots as the absorption dips marked 417 and 418. When the field's intensity F_{Off}² is strong enough that we can measure a line splitting (splitting larger than the resolved linewidth), on the theory plots the splitting 415 causes lines 423 and 424 to appear, and splitting 416 causes lines 425 and 426 to appear. This effect is observed in the experimental graphs 400 at the energies corresponding to 417 and 418 on each graph.

Exemplary embodiments produce this quantum system that exhibits this splitting. This splitting is observed to split non-linearly, owing to the combination of Bessel functions, and is predictable by theory, as illustrated by the comparison of graphs 400 and graphs 403.

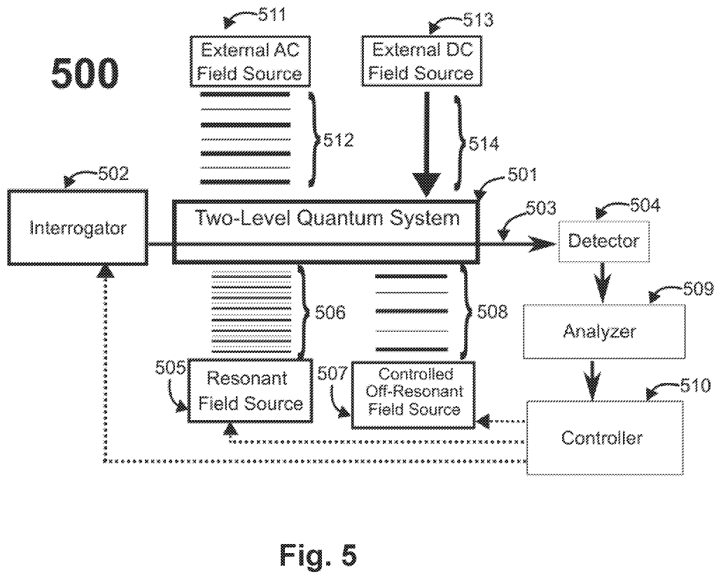

FIG. 5 shows a schematic representation of an exemplary embodiment of a measurement apparatus 500. The center of the system is a two-level quantum system 501, which may be, e.g., Rydberg atoms in an alkali vapor cell. To probe the energy of one of those states, and potentially to populate the two-level system, an interrogator 502 (for example, spectroscopy using controlled, scanning or locked frequency lasers) may be used to sample the quantum system 501. The resulting beam 503 may be measured by some detector 504 (e.g., photodiode, single photon counter, ionization in vacuum, etc.). Additionally, a controller 510 may provide feedback and general experimental control to enable different forms of measurement. By processing the detected data using an analyzer 509, for example with appropriate quantum theory, fields that the two-level quantum system 501 is subject to can be inferred.

Continuing to refer to FIG. 5, a resonant field 506 is applied to the two-level quantum system 501, which produces a controlled Autler-Townes splitting of the two-level system 501. This resonant field 506 is applied by some field source 505, which may consist of a signal generator and the physical structure which applies or radiates the fields and may be controlled by controller 510. The results of analyzer 509 may be used with controller 510 of the resonant field 505/506 to keep its frequency resonant with the two-level system 501 as additional field(s) shift the levels. The amplitude of the resonant field 506 may also be controlled by controller 510, as this ‘tunes’ the splitting frequency. If an off-resonant field 508 is applied from an off-resonant field source 507 (which may be any appropriate source known to those skilled in the art), and the field is strong enough, an additional line splitting effect can be observed when probing energies 502 of the system 501. This is useful for arbitrary frequency field amplitude metrology.

If the off-resonant source 507 is controlled, this system 501 may be probed by a beam 503 to measure additional external fields or signals. For example, an additional AC field 512 from an arbitrary external field source 511 (for example, a radio transmission), can be detected by the intermodulation with the applied off-resonant field 507/508, if they are significantly different in frequency. In the same or another exemplary embodiment, if they are near in frequency, then one can use the ‘beat note’ method to measure a weak AC field's 512 amplitude and phase. By controlling both the off-resonant 507 and the resonant 505 sources, as well as the spectroscopy fields 502, external ac fields 511 can be detected by different methods. In the same or separate exemplary embodiments, DC fields 514 created by an arbitrary source 513 can be detected and measured by observing the “first order” splitting located at Ω≈ω_{Off}, which represents the “cross-term”, mixing the F_{DC} 514 and F_{Off} 508 field amplitudes. This measurement may be made more sensitive by controlling the Off-resonant field 507 508 to be larger in amplitude.

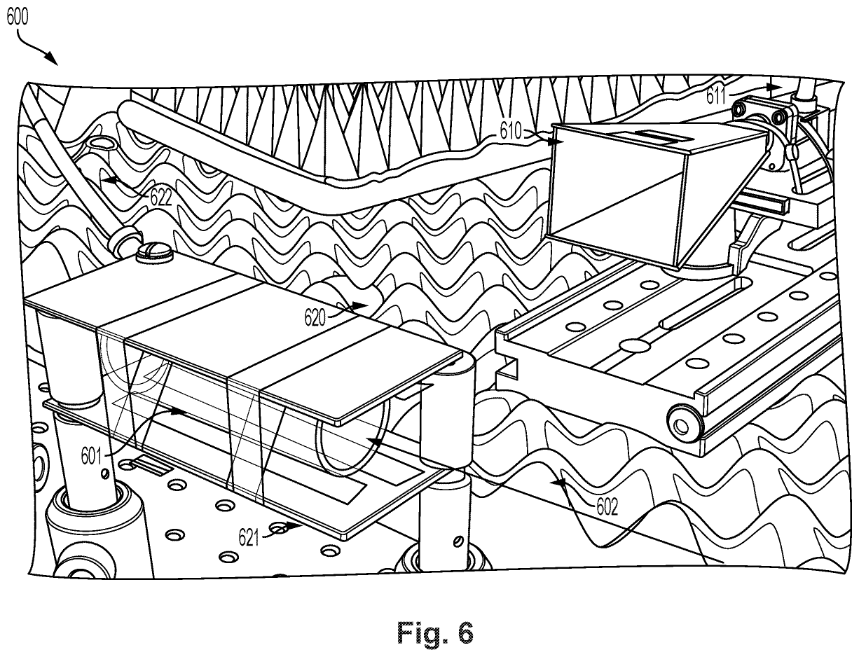

Referring now to FIG. 6, an exemplary measurement apparatus is shown at 600. The apparatus 600 includes a quantum medium 601, a feedline from a controller 611 that controls an electromagnetic horn 610 to generate a resonant field to thereby create a two-level quantum system within the quantum medium 601. An optional feedline from a second controller 622 causes plates 620, 621 to generate an off-resonant field in the quantum medium. An interrogation beam 602 passes through the quantum medium to measure the spectral properties thereof, thereby allowing measurement of these fields or additional incident electromagnetic fields.

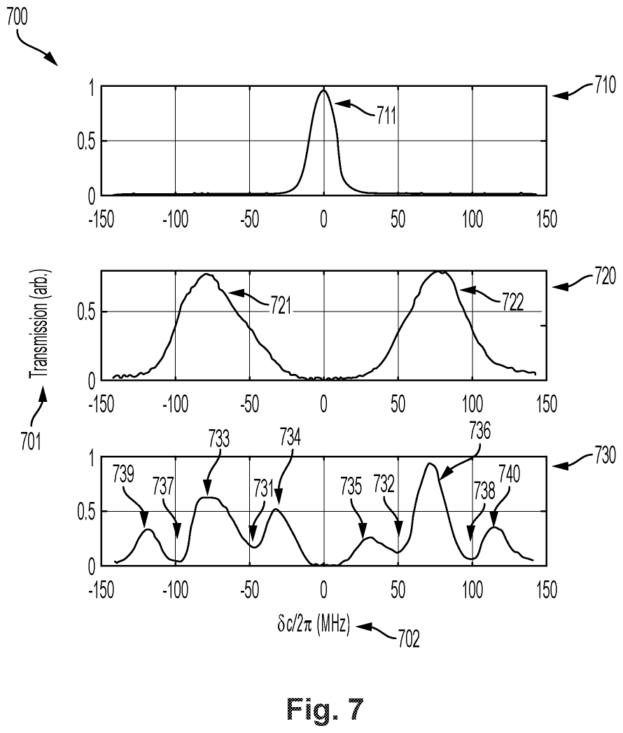

Referring now to FIG. 7, graph set 700 demonstrates example data from an exemplary embodiment. Two-laser electromagnetically induced transparency may be used to create and probe atomic Rydberg states, which are strongly polarizable (~3 GHz/(V/cm)\hat{ }2 and 12 GHz/(V/cm)\hat{ }2), and have a strong dipole moment (~2 GHz/(V/cm)) between them, the 56 D_{5/2} and the 54 F_{7/2} state of Cesium. All graphs of 700 are plotted on the same axes of scanned laser detuning 702, and optical transmission 701 of the ‘probe’ laser through the vapor cell. Graph 710 shows the observation of one of the states in our two-level system, the 56 D_{5/2} state. This state's energy is observed by the peak 711, and this frequency location sets the 0 offset for the detuning axis, in addition to removing the stark shift δ_{Stark} for illustration. Graph 720 represents the observation of the same state in a superposition of two energy states, called the |−> state observed by peak 721, and the |+> peak, observed by peak 722. The observed state is affected by the significant resonant field amplitude, enough to cause a Rabi frequency Ω of approximately 150 MHz, although spatial non-uniformity of this field causes it to reach from below 100 MHz to above 200 MHz in certain parts of the vapor cell, as observed by the transmission amplitude in the spectrum, which represents state population at that energy. In the graph 730, a strong off-resonant field is added with ω_{Off}=100 MHz, causing observed line splittings at laser detuning δ_{C}/2π=±50 MHz and ±100 MHz (again, after removing the stark shift δ_{Stark}). The “first order” splittings at 731 and 732 are observed as an initial shift down in transmission, eventually causing two distinct peaks to appear. The splitting 731 causes the lines 733 and 734 to appear, and the splitting 732 causes the lines 735 and 736 to appear. These splittings correspond to the experimental data presented in the row of graphs 400, the features 421 and 422. The “second order” splittings at 737 and 738 are observed as an initial shift down in transmission, eventually causing two distinct peaks to appear. The splitting 737 causes the lines 739 and 733 to appear, and the splitting 738 causes the lines 736 and 740 to appear. These splittings correspond to the experimental data presented in the row of graphs 400, the features 417 and 418. Note that the features 733 and 736 are shared between the lines in this example, due to the large range of Rabi Frequencies Ω sampled by the spatial non-uniformity of the system.

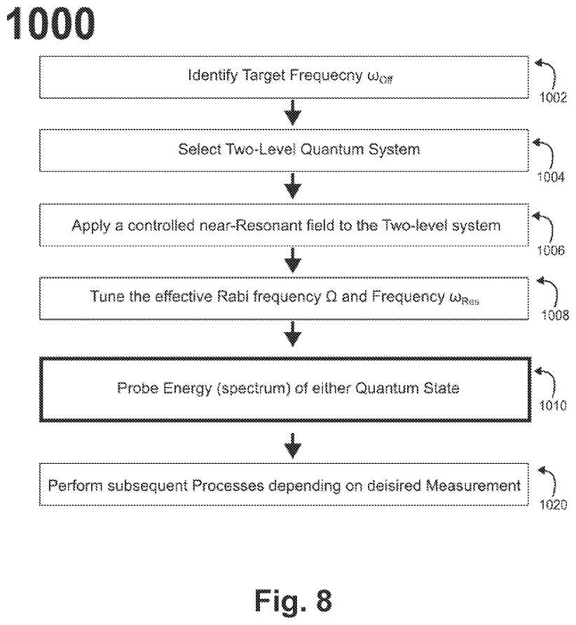

In FIG. 8, process 1000 outlines an exemplary embodiment of the invention and one that other exemplary embodiments use as a starting point. These other exemplary embodiments correspond to different styles of measurement enabled by the invention and are discussed further below.

In step 1002, a Target Frequency 1002 is identified. Exemplary embodiments can probe frequencies ω_{Off} which are larger than the linewidth (spectral resolution of the readout system) as the low frequency limit. The high frequency limit is given by the achievable range of Rabi frequency Ω, which scales linearly with the field amplitude of the resonant field F_{Res}, and also depends on detuning δ from the two-level resonance. Due to the non-linear and non-monotonic behavior of the sideband population as described by the Bessel functions, sensitivity to fields may be improved with lower frequency, as J_{N}(1/ω) in general. In some exemplary embodiments the frequency of interest is predetermined. In some exemplary embodiments, the frequency of interest may be in some sense unknown and therefore the frequency of interest may change moment to moment as frequencies are scanned to determine the presence, absence, and other qualities of any electromagnetic fields present.

With a target frequency having been selected, at block 1004 a two-level quantum system will be selected and can be judged for suitability for the desired measurement. A preferred embodiment includes a pair of states sensitive to electric fields to be selected from the set of excited states called Rydberg atoms, which have high electric polarizability, and strong transition dipole moments.

By applying a controlled, tunable “Resonant” field to a quantum media in block 1006, the two-level system selected at block 1004 is created. The states of the system create a dressed atom system with an avoided level crossing, demonstrating Autler-Townes splitting of the observable energy states.

By controlling the frequency ω_{Res} of the Resonant field to remain near the two-state resonance at block 1008, we can control this line splitting Ω with the field amplitude of the resonant field applied.

With this field applied and strongly splitting the state, the energy spectrum of one of the states in the driven two-level system is probed and readout at block 1010. In the case of Rydberg atom electrometry, it is common to use a two-photon ladder scheme EIT where frequency of one laser is swept while the transmission of the other laser is monitored. An arbitrary number of lasers, radio waves, DC electromagnetic fields, ionization, and/or atomic interference may be used to create and/or probe the energies at block 1010 of the two-level system selected in 1004. With a strong Resonant driving field from step 1008 and optionally continuous monitoring of the energy spectrum from step 1010, the system is sensitive to Off-resonant fields ω_{Off} which are nearly matched by the Rabi frequency Ω, or when Ω=2ω_{Off}. This “sensitivity” to fields of this frequency is due to an additional line splitting or avoided energy level crossing of the quantum system, which is observable in the spectral measurements 1010 of the combined system.

It is noted that this exemplary embodiment does not contain an applied Off-resonant field, as this may be an external signal to be measured by this process.

In optional subsequent processes 1020, the field may be applied and controlled for measurement sensitivity, phase reference, and other purposes, depending on the desired application of this invention.

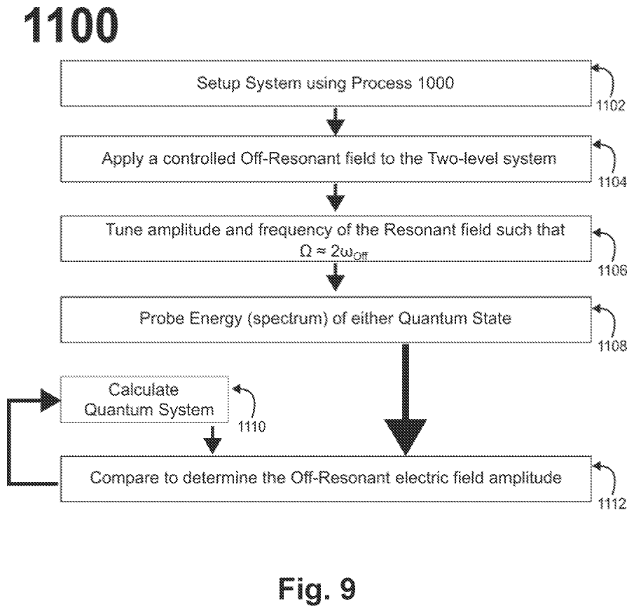

Referring now to FIG. 9, process 1100 can be used to determine the electric field intensity of a field of arbitrary frequency ω_{Off}. The system is prepared 1102 as described by process 1000. Next, a controlled Off-Resonant field is applied to the system at block 1104, with an amplitude large enough to cause a desired splitting effect. The Resonant field is tuned at block 1106 in frequency and amplitude such that the system demonstrates (nearly-)symmetric Autler-Townes splitting with Rabi frequency Ω “matched” to approximately 2ω_{Off}. By probing the energy of either quantum state at block 1108 in the two-level system, the spectrum can be measured as a result of the controlled applied power and frequency of both the applied Resonant field from block 1106 and the Off-resonant field from block 1104. Using calculations of the Quantum state at block 1110 for expected field parameters, a measurement can be made at block 1112 by comparing the observed spectra with ones predicted by theory. Using an iterative process with the parameters entered into the calculation, the difference between the theory and measurement can be minimized of fit to obtain a determination at block 1112 of the electric field amplitude, using potentially a single spectrum measurement. There is no easy closed form expression to convert the observed atomic line splitting 1108 into an electric field, and so we perform an iterative ‘fitting’ routine, represented by the arrow pointing from 1112 to 1110.

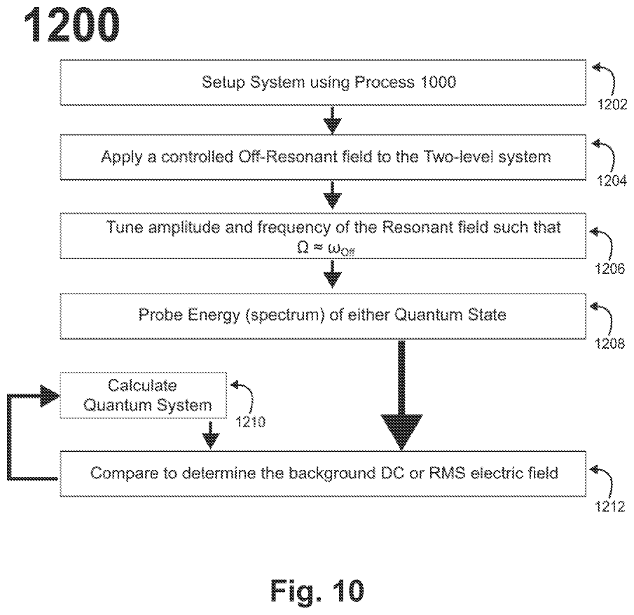

Referring now to FIG. 10, Process 1200 can be used to determine the electric field intensity of a field of arbitrary DC electric field, or analogously the background electric field time averaged intensity. The system is prepared at block 1202 as described by process 1000. Next, a controlled Off-Resonant field is applied to the system at block 1204, with an amplitude large enough to cause the desired splitting effect. The Resonant field is tuned at block 1206 in frequency and amplitude such that the system demonstrates nearly-symmetric Autler-Townes splitting with Rabi frequency Ω “matched” to approximately ω_{Off}. By probing the energy of either quantum state at block 1208 in the two-level system, we can measure the spectrum as a result of the controlled applied power and frequency of both the applied Resonant field at 1206 and the Off-resonant field at 1204. Using calculations of the Quantum state at 1210 for expected field parameters, a measurement of a DC electric field can be made by comparing at 1212 the observed spectra with ones predicted by theory at 1210. Using an iterative process with the parameters entered into the calculation, the difference between the theory and measurement can be minimized of fit to obtain a determination at 1212 of the electric field amplitude, using potentially a single spectrum measurement. There is no easy closed form expression to convert the observed atomic line splitting at 1208 into an electric field, and so we perform an iterative ‘fitting’ routine, represented by the arrow pointing from 1212 to 1210.

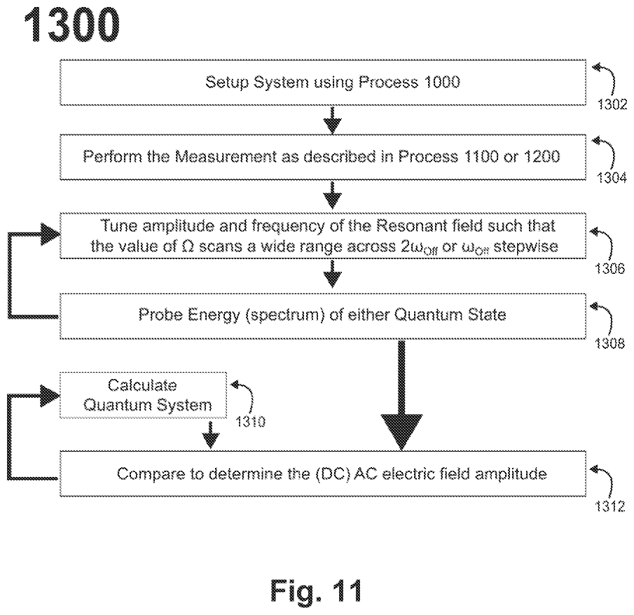

The exemplary process 1300 shown in FIG. 11 represents an extension or improvement to either electrometry methods in process 1100 or 1200, by scanning Ω in a range across the target frequency. This process begins by having setup using process 1000 as step 1302. The amplitude of the Resonant field is set at block 1304 such that Rabi frequency Ω is near 2ω_{Off} or ω_{Off} (whether modifying process 1100 or 1200, respectively). The value of Ω is scanned at block 1306 across the target frequency value, and for each value, the energy spectrum is measured 1308. This process happens repetitively across the scan range of Ω, and the data is measured for each value and preserved. Using these multiple energy spectrum measurements, computation of the quantum energy levels 1310 can determine 1312 the AC and/or DC field amplitude that caused the observed spectra. By measuring the splitting across a range (Ω−ω_{Off}), the effective field can be extracted from a fit of the line splittings in multiple cases simultaneously more accurately than in a single measurement and made insensitive to accidental detuning. For example, this sort of measurement is represented by the “avoided crossing” shown in FIG. 4, graphs 403 at the line splittings 419, 420 (corresponding to process 1200) and splittings 415, 416 (corresponding to process 1100). In the event that Ω≠ω_{Off}, it may be difficult to achieve the resonant condition without feedback from observation. This process allows for an improvement of the electric field measurement resolution without requiring that the Rabi matching condition is exactly met, by scanning over a range and fitting.

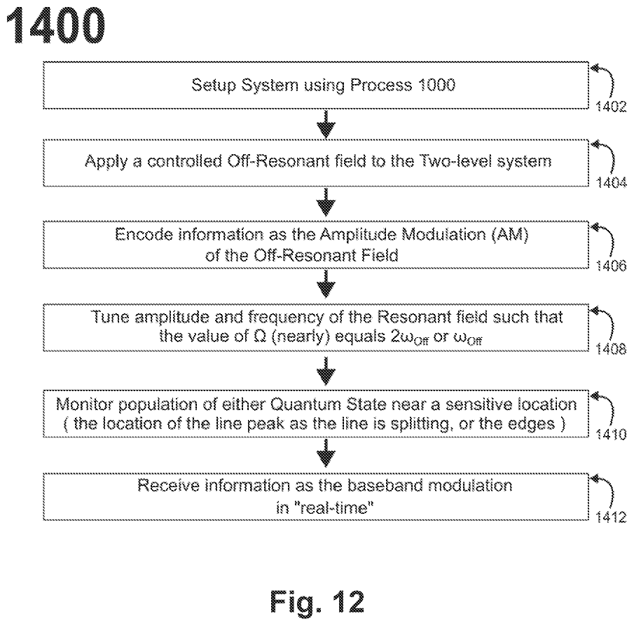

Referring now to FIG. 12, illustrated is process 1400 for receiving amplitude modulated (AM) radio signals. First, the system is prepared according to process 1000 in step 1402. A ‘carrier’ Off-resonant field is applied to the system at 1404. This Off-resonant field should be strong enough in amplitude to cause a significant transmission change, or a line splitting when probed. Information is encoded in this carrier by the temporal modulation of the amplitude of the Off-Resonant field at 1406.

For energy probing, rather than scanning across the energy spectrum, the probing device is held fixed at a sensitive location, and the population/transmission is measured continuously at 1410. Known sensitive locations include the center of an unsplit peak, which becomes the center of the splitting, having optimal changes in output signal change for a change in field amplitude. Additional sensitive areas include the high-slope edge of the spectral lines, and also continuously along the line with varying sensitivity. Any one or more of these or other suitable locations may be chosen in various exemplary embodiments of the invention.

The temporal transmission value, or analogous population measurements are read out in real-time at 1412. Since the effect is a line splitting, this has the effect of “demodulating” or “down-converting” the signal from the carrier frequency automatically into the baseband output signal. Classical radio receivers receive signals at the Carrier frequency and need to frequency mix or otherwise analyze the carrier wave for modulations in signal. The effect of using a quantum system with a splitting is that the output signal at 1412 corresponds to the intensity of the Off-resonant field at 1406 and doesn't evolve at the carrier frequency.

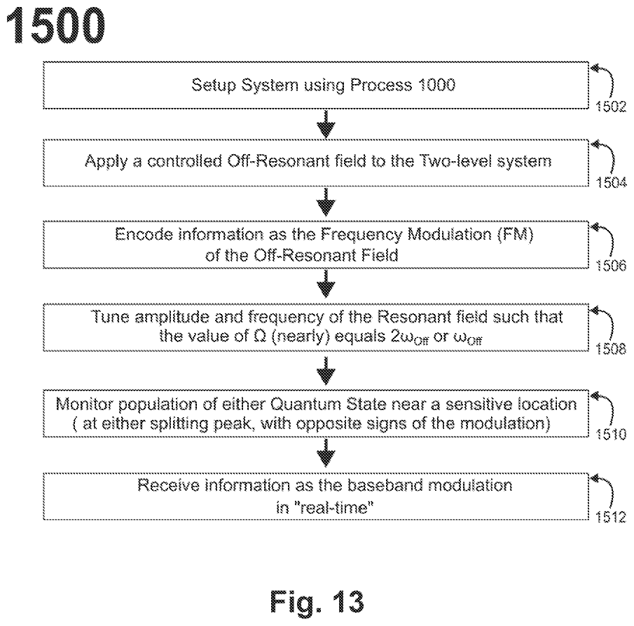

Turning now to FIG. 13, illustrated is process 1500 for receiving frequency modulated (FM) radio signals. First, the system is prepared according to process 1000 in step 1502. A ‘carrier’ Off-Resonant field is applied to the system 1504. This Off-resonant field must be strong enough in amplitude to cause a significant transmission change, or a line splitting when probed. Information is encoded in this carrier by the temporal modulation of the frequency of the Off-Resonant field 1506. For energy probing, rather than scanning across the energy spectrum, the probing device is held fixed at a sensitive location, and the population/transmission is measured continuously 1510. Known sensitive locations for the case of frequency modulation are due to an effective population imbalance between the two splitting peaks. Therefore, optimal changes in output signal change due to a change in frequency are located at the center of either splitting peak, which will have opposite reactions to the sign of the frequency difference (Ω−ω_{Off}). The temporal transmission value, or analogous population measurements are read out in real-time 1512. Since the effect is a line splitting, this has the effect of “demodulating” or “down-converting” the signal from the carrier frequency automatically into the baseband output signal. Classical radio receivers receive signals at the Carrier frequency and need to frequency mix or otherwise analyze the carrier wave for modulations in signal. The effect of using a quantum system with a splitting is that the output signal 1512 corresponds to the frequency difference of the Rabi frequency and the Off-resonant field 1506 and doesn't evolve at the carrier frequency.

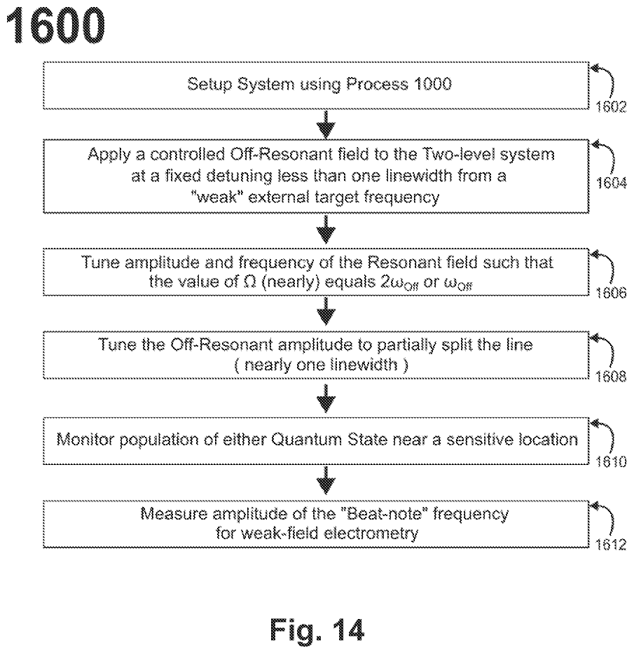

Turning now to FIG. 14, illustrated is process 1600 to measure radio fields of arbitrary frequency which are “weak,” meaning not strong enough to cause a significant line splitting or adjustment to the spectrum on their own. By using a stronger, controlled Off-resonant field, which acts as a Local Oscillator (LO), these fields can be measured by their effect. The system is constructed according to Process 1000 in step 1602. An Off-resonant field is applied at 1604 such that the frequency is within one linewidth (for the probing system) of a weak target frequency. The amplitude and frequency of the Resonant field are adjusted so that the Rabi frequency nearly matches ω_{Off} or 2ω_{Off} in step 1606. The amplitude of the Off-resonant field should be adjusted 1608 to partially split the line such that it is optimally sensitive to small perturbations in field amplitude, typically a splitting of one linewidth. The probing device is set to measure these perturbations from shifts in effective field amplitude 1610. When two frequencies are applied to the same system, often the sum and difference frequencies are observed, where the difference is often called the “beat note”, which provides a modulating amplitude envelope for the mean frequency. This creates a system with amplitude that modulates at a frequency determined by the difference of the strong applied Off-resonant LO field and the target field frequency. The probing device is held fixed 1610 at a sensitive location, and the population/transmission is measured continuously. Known sensitive locations include the center of an unsplit peak, which becomes the center of the splitting, having optimal changes in output signal change for a change in field amplitude. Additional sensitive areas include the high-slope edge of the spectral lines and also continuously along the curve with varying sensitivity. The output of this measurement 1612 will be a signal at the beat-note frequency, with amplitude determined by that of the external target field. For example, the beat-note frequency can be read through a Lock-in amplifier with a reference frequency provided to measure very small amplitude radio waves of arbitrary frequency.

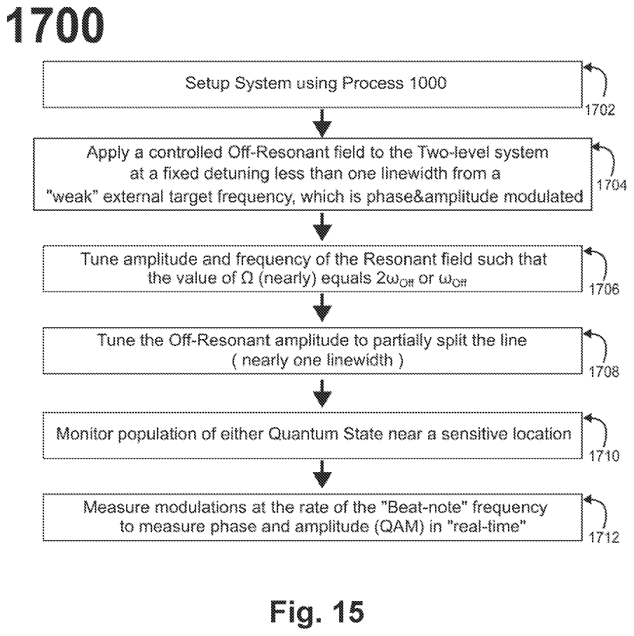

Turning now to FIG. 15, illustrated is process 1700 to measure radio fields of arbitrary frequency which are not strong enough to cause a significant line splitting or adjustment to the spectrum on their own. By using a stronger, controlled Off-resonant field, which acts as a Local Oscillator (LO), these fields can be measured by their effect. The system is constructed according to Process 1000 in step 1702. An Off-resonant field is applied at block 1704 such that the frequency is within one linewidth (for the probing system) of a weak target frequency. This target field is assumed to carry information in the form of phase and/or amplitude modulation, generally called QAM. The amplitude and frequency of the Resonant field are adjusted so that the Rabi frequency nearly matches ω_{Off} or 2ω_{Off} in step 1706. The amplitude of the Off-resonant field should be adjusted at block 1708 to partially split the line such that it is sensitive to small perturbations in field amplitude. The probing device is set to measure these perturbations from shifts in effective field amplitude at block 1710. When two frequencies are applied to the same system, often the sum and difference frequencies are often observed, where the difference is often called the “beat note”, which provides a modulating amplitude envelope for the mean frequency. This creates a system with amplitude that modulates at a frequency determined by the difference of the strong applied Off-resonant LO field and the target field frequency. The probing device is held fixed at block 1710 at a sensitive location, and the population/transmission is measured continuously. Known sensitive locations include the center of an unsplit peak, which becomes the center of the splitting, having optimal changes in output signal change for a change in field amplitude. Additional sensitive areas include the high-slope edge of the spectral lines, and also continuously along the curve with varying sensitivity. The output of this measurement at 1712 will be a signal at the beat-note frequency, with phase and amplitude determined by the phase and amplitude of a QAM-modulated target carrier field. This allows real-time baseband reception of the baseband signal at block 1712, when the Rabi frequency and probing system are properly tuned.

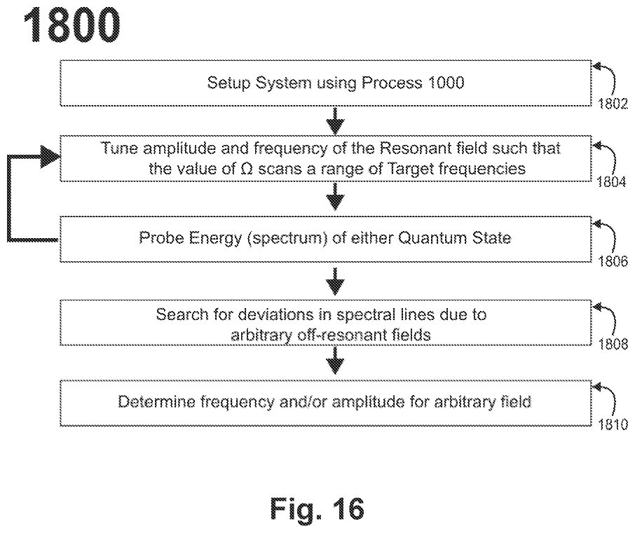

Referring now to FIG. 16, illustrated is process 1800 that is analogous to a classical device called a Spectrum Analyzer, which determines the radio power density across a measured frequency spectrum. Rather than a single target field to tune into, this method intends to “search” for, in general, many simultaneous radio fields, realizing measurements of amplitude and frequency for each. The process begins by preparing the system according to process 1000, in step 1802. The Rabi frequency of the Resonant field is set to an arbitrary value at block 1804, and the energy spectrum is obtained at block 1806. Then, iteratively, we can scan or step through values of the Rabi frequency in block 1804, taking an energy spectrum measurement at block 1806 for each. Then, by analyzing the patterns at block 1808 and especially any deviations in signal at particular values of the Rabi Frequency Ω, the frequency and intensity of arbitrary frequency fields that affect the two-level quantum system can be determined at block 1810. Additional frequency components representing the sum and difference, or “intermodulation” frequencies also appear in the spectrum, making measurements slightly more complicated but entirely possible to measure still. This method also resembles the scanning process 1300 that was used for a single known frequency, but in this case an arbitrary number of weaker fields can be searched for that aren't strong enough for a full line splitting, just causing slight absorption dips in the signal.

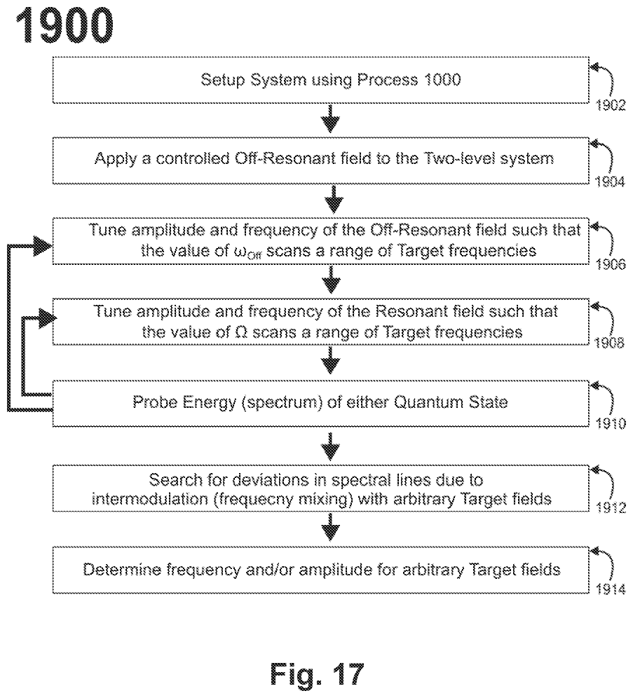

Turning now to FIG. 17, illustrated is process 1900 that is like process 1800, but includes the use of a strong Off-resonant field as an LO, to determine the radio power density across a measured frequency spectrum. The process begins by preparing the system according to process 1000, in block 1902. An Off-Resonant field is applied with frequency ω_{Off} at block 1906, and enough power to cause a significant change in the energy states. The Rabi frequency of the Resonant field is set to match ω_{Off} or 2ω_{Off} at block 1908, and the energy spectrum is obtained at block 1910. Then, iteratively, we can scan or step simultaneously through values of the LO frequency ω_{Off} at block 1906, and Rabi frequency at block 1908, taking an energy spectrum measurement at block 1910 for each. Then, by analyzing the patterns at block 1912 and especially looking for additional intermodulation tones, the frequency and intensity of arbitrary weak external fields that affect the two-level quantum system can be determined at block 1914. This process uses the power of the LO to amplify the smaller signals of external fields to a more observable effect.

Elements of exemplary measurement apparatuses can be made of a material that is physically or chemically resilient in an environment in which the apparatus is disposed. Exemplary materials include a metal, ceramic, thermoplastic, glass, semiconductor, and the like. The elements of exemplary measurement apparatuses can be made of the same or different material and can be monolithic in a single physical body or can be separate members that are physically joined.

Exemplary embodiments can be made in various ways. It should be appreciated that exemplary measurement apparatuses include a number of optical, electrical, or mechanical components, wherein such components can be interconnected and placed in communication (e.g., optical communication, electrical communication, mechanical communication, and the like) by physical, chemical, optical, or free-space interconnects. The components can be disposed on mounts that can be disposed on a bulkhead for alignment or physical compartmentalization. As a result, exemplary measurement apparatuses can be disposed in a terrestrial environment or space environment. Elements of exemplary measurement apparatuses can be formed from silicon, silicon nitride, and the like although other suitable materials, such ceramic, glass, or metal can be used. Accordingly, exemplary measurement apparatuses can be made by additive or subtractive manufacturing or any combination thereof. In an embodiment, elements of an exemplary measurement apparatus are selectively etched to remove various different materials using different etchants and photolithographic masks and procedures. The various layers thus formed can be subjected to joining by bonding to form one or more components of an exemplary measurement apparatus.

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules (such as a controller or analyzer) described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory. EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

1. A measurement apparatus for sensing electro-magnetic fields, the measurement apparatus comprising:
a quantum medium;
a resonant field source configured to create a two-level quantum system in the quantum medium;
a controller configured to tune an effective Rabi frequency of the two-level quantum system based on a predetermined frequency of interest; and
an interrogator configured to probe the two-level system, thereby measuring properties of an external electromagnetic field near the predetermined frequency of interest.

2. The measurement apparatus of claim 1, wherein the interrogator comprises a laser source and a photo diode configured to receive an interrogation beam emitted by the laser source probing the two-level quantum system.

3. The measurement apparatus of claim 1, further comprising an off-resonant field source configured to cause a Townes-Merritt effect in the two-level system by applying an off-resonant field to the two-level system.

4. A process for measuring electromagnetic fields, the process comprising:
applying a near-resonant field to a quantum medium to create a two-level quantum system;
tuning an effective Rabi frequency based on a predetermined frequency of interest; and
probing the two-level system to thereby measure properties of an electromagnetic field near the predetermined frequency of interest.

5. The process of claim 4, wherein the step of probing includes:
using a two-photon ladder scheme electromagnetically induced transparency wherein a frequency of a first laser is swept while a transmission through the two-level quantum system of a second laser is monitored.

6. The process of claim 4, further comprising the step:
applying an off-resonant field to the two-level quantum system, the off-resonant field having an amplitude of sufficient magnitude to cause a change in a probed energy spectrum.

7. The process of claim 4, further comprising the step of:
iteratively comparing observed spectra obtained during the step of probing and calculations of a quantum state of the two-level quantum system.

8. The process of claim 4, further comprising the steps of:
scanning the effective Rabi frequency across a target frequency value; and
measuring an energy spectrum at each scanned frequency.

9. The process of claim 8, further comprising the step of:
using the measured energy spectra to determine a field amplitude that caused any observed splitting across the target frequency value.

10. The process of claim 6, wherein the predetermined frequency of interest is an amplitude-modulated carrier frequency and the step of probing includes probing continuously at a fixed sensitive location.

11. The process of claim 10, wherein the fixed sensitive location is one of a center of an unsplit peak, or a high-slope edge of spectral lines.

12. The process of claim 6, wherein the predetermined frequency of interest is a frequency-modulated carrier frequency and the step of probing includes probing continuously at a fixed sensitive location.

13. The process of claim 12, wherein the fixed sensitive location is at a center of either splitting peak.

14. The process of claim 4, further comprising the steps of:
applying an off-resonant field having a frequency within one linewidth of a target frequency;
adjusting an amplitude and frequency of the resonant field and an amplitude of the off-resonant field to partially split a spectral line, thereby making the location sensitive to perturbations in field amplitude that are small relative amplitudes of the applied fields; and
wherein the step of probing includes continuously measuring amplitude of a beat-note frequency at a sensitive location, thereby measuring an amplitude of an external field at the target frequency.

15. The process of claim 14, wherein the sensitive location is one of a center of an unsplit peak, or a high-slope edge of spectral lines.

16. The process of claim 4, further comprising the steps of:
applying an off-resonant field having a frequency within one linewidth of a target frequency;
adjusting an amplitude and frequency of the resonant field and an amplitude of the off-resonant field to partially split a spectral line, thereby making the location sensitive to perturbations in field amplitude that are small relative amplitudes of the applied fields; and
wherein the step of probing includes continuously measuring modulations of rate of a beat-note frequency at a sensitive location, thereby measuring phase and amplitude of an external field at the target frequency.

17. The process of claim 16, wherein the sensitive location is one of a center of an unsplit peak, or a high-slope edge of spectral lines.

18. A process for measuring electromagnetic fields, the process comprising:
applying a near-resonant field to a quantum medium to create a two-level quantum system;
iteratively scanning through values of Rabi frequency;
probing the two-level system at each scanned Rabi frequency; and
analyzing patterns from the probing to determine frequency and intensity of incident off-resonant fields.

19. The process of claim 18, further comprising the step of:
iteratively applying an off-resonant field configured as a local oscillator; and
probing the two-level system at each value of the local oscillator.

20. The process of claim 18, wherein the step of analyzing includes looking for additional intermodulation tones.
